(19) United States
(12) Patent Application Publication
(10) Pub. No.: US 2026/0110973 A1
(43) Pub. Date: Apr. 23, 2026

(54) SIMULATION-ASSISTED METHODS AND SOFTWARE TO GUIDE SELECTION OF PATTERNS OR GAUGES FOR LITHOGRAPHIC PROCESSES

(71) Applicant: ASML NETHERLANDS B.V., Veldhoven (NL)

(72) Inventors: Lu GUO, San Jose, CA (US); Chenji ZHANG, San Jose, CA (US); Jun CHEN, San Jose, CA (US); Mu FENG, San Jose, CA (US)

(73) Assignee: ASML NETHERLANDS B.V., Veldhoven (NL)

(21) Appl. No.: 19/117,361

(22) PCT Filed: Sep. 22, 2023
(86) PCT No.: PCT/EP2023/076166

§ 371 Date: Mar. 31, 2025

Related U.S. Application Data
(60) Provisional application No. 63/419,420, filed on Oct. 26, 2022.

(51) Int. Cl. G03F 7/00

(52) U.S. Cl. CPC G03F 7/705; G03F 7/70441; G03F 7/70655; G03F 7/706839; G03F 7/706845

(57) ABSTRACT

Methods, computer programs, and systems are disclosed, with one method including characterizing a depth variation of a predicted result within a feature of a pattern from a lithography simulation. The method evaluates the depth variation characterization and selects patterns or gauges based on the depth variation evaluation. In some embodiments, the evaluating can be based on an aerial image (AI) depth sensitivity having the depth variation.

### CROSS-REFERENCE TO RELATED APPLICATIONS

This application claims priority of U.S. application 63/419,420 which was filed on Oct. 26, 2022 and which is incorporated herein in its entirety by reference.

### TECHNICAL FIELD

The description herein relates generally to analysis of simulated or printed patterns. More particularly, the disclosure includes apparatus, methods, and computer programs for determining patterns or gauges appropriate for use with imaging and/or modelling.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g., comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus may also be referred to as a stepper. In an alternative apparatus, a step-and-scan apparatus can cause a projection beam to scan over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is can be referred to as low-k1 lithography, according to the resolution formula CD=k1×λ/NA, where λ is the wavelength of radiation employed (e.g., 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, and their structures continue to become more complex, accuracy and throughput in defect detection and inspection become more important. The overall image quality depends on a combination of high secondary-electron and backscattered-electron signal detection efficiencies, among others. Backscattered electrons have higher emission energy to escape from deeper layers of a sample, and therefore, their detection may be desirable for imaging of complex structures such as buried layers, nodes, high-aspect-ratio trenches or holes of 3D NAND devices. For applications such as overlay metrology, it may be desirable to obtain high quality imaging and efficient collection of surface information from secondary electrons and buried layer information from backscattered electrons, simultaneously, highlighting a need for using multiple electron detectors in a SEM. The ability to monitor and detect IC non-idealities may be limited by an image quality of the inspection system, including by the alignment or calibration of an SEM system.

### SUMMARY

Systems, methods, and computer software are disclosed for determining patterns or gauges appropriate for use with imaging and/or modelling. In one aspect, a method includes characterizing a depth variation of a predicted result within a feature of a pattern from a lithography simulation; evaluating the depth variation characterization; and selecting patterns or gauges based on the depth variation evaluation.

In some variations, the predicted result can represent a resist contour or a resist CD and the depth variation characterization can be a resist contour variation in depth or a resist CD variation in depth.

In some variations, the predicted result can represent an aerial image contour or an aerial image CD and the depth variation characterization can be aerial image contour variation in depth or an aerial image CD variation in depth.

In some variations, the predicted result can represent an etch contour or an etch CD and the depth variation characterization can be etch contour variation in depth or an etch CD variation in depth.

In some variations, the evaluating can be based on an aerial image (AI) depth sensitivity having the depth variation, the AI depth sensitivity is based on a first derivative of a CD as a function of depth, and the AI depth sensitivity can be based on a total change in CD compared to a total change in depth.

In some variations, the selecting can be based on the aerial image depth sensitivity being less than a threshold. The method can also include performing optical proximity correction (OPC) modelling utilizing the patterns or gauges.

In some variations, the selecting can be based on the aerial image depth sensitivity being greater than a threshold.

In some variations, the method can include performing local OPC on the feature in the pattern where the aerial image depth sensitivity is greater than the threshold to reduce a depth variation of the pattern. The local OPC can include detecting a hotspot location in the pattern and performing the local OPC at the hotspot location. The local OPC can reduce a difference between a first contour of the feature at a first depth and a second contour of the feature at a second depth. The difference can be between a first location on the first contour and a second location on the second contour, the difference determining a side wall angle of the feature.

In some variations, the method can include generating SEM images of the pattern while excluding a portion of the SEM images where the aerial image depth sensitivity is above the threshold and performing OPC model building utilizing the SEM images.

In some variations, the method can include generating SEM images of the pattern where the aerial image depth sensitivity is above the threshold and performing stochastic modelling utilizing the SEM images.

In some variations, the method can include obtaining SEM images of the selected patterns or gauges.

In some variations, the method can include obtaining comprising discarding a portion of the SEM images where the aerial image depth sensitivity is above the threshold. The method can also include performing OPC model building utilizing the SEM images.

In some variations, the method can include performing stochastic modelling of the pattern based on a portion of the SEM images where the aerial image depth sensitivity is above the threshold.

In some variations, the method can include calibrating a stochastic failure model based on a portion of the SEM images.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 illustrates a block diagram of various subsystems of a lithographic projection apparatus, according to an embodiment of the present disclosure.

FIG. 2A illustrates an exemplary flow chart for simulating lithography in a lithographic projection apparatus, according to an embodiment of the present disclosure.

FIG. 2B is a schematic diagram of an exemplary electron beam tool, according to an embodiment of the present disclosure.

FIG. 3 illustrates exemplary predicted results for a portion of a pattern having a depth variation, according to an embodiment of the present disclosure.

FIG. 4 illustrates an exemplary process for selecting patterns or gauges based on a depth variation evaluation, according to an embodiment of the present disclosure.

FIG. 5 illustrates an exemplary process for various operations that can be performed based on a process stage and an evaluation of the AI depth sensitivity, according to an embodiment of the present disclosure.

FIG. 6 illustrates an exemplary process for reducing a depth variation of a pattern, according to an embodiment of the present disclosure.

FIG. 7 is a block diagram of an example computer system, according to an embodiment of the present disclosure.

FIG. 8 is a schematic diagram of a lithographic projection apparatus, according to an embodiment of the present disclosure.

FIG. 9 is a schematic diagram of another lithographic projection apparatus, according to an embodiment of the present disclosure.

FIG. 10 is a detailed view of the lithographic projection apparatus, according to an embodiment of the present disclosure.

FIG. 11 is a detailed view of the source collector module of the lithographic projection apparatus, according to an embodiment of the present disclosure.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic methods.

An example of a programmable LCD array is given in U.S. Pat. No. 5,229,872, which is incorporated herein by reference.

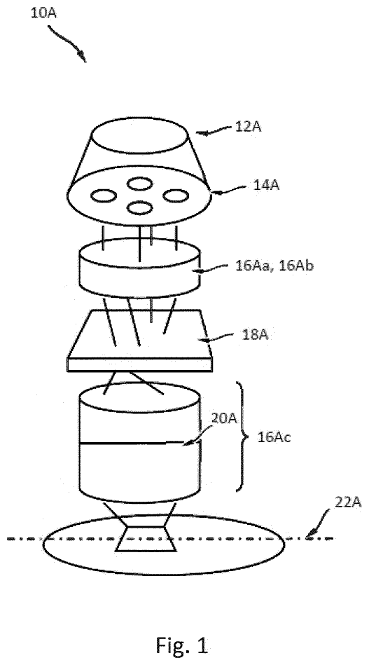

FIG. 1 illustrates a block diagram of various subsystems of a lithographic projection apparatus 10A, according to an embodiment of the present disclosure. Major components are a radiation source 12A, which may be a deep-ultraviolet excimer laser source or other type of source including an extreme ultraviolet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

The mask transmission function may have a variety of different forms. One form is binary. A binary mask transmission function has either of two values (e.g., zero and a positive constant) at any given location on the patterning device. A mask transmission function in the binary form may be referred to as a binary mask. Another form is continuous. Namely, the modulus of the transmittance (or reflectance) of the patterning device is a continuous function of the location on the patterning device. The phase of the transmittance (or reflectance) may also be a continuous function of the location on the patterning device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1, 0.2, 0.3, etc.) instead of binary value of either 0 or 1. In an embodiment, CTM may be a pixelated gray scale image, where each pixel having values (e.g., within a range [−255, 255], normalized values within a range [0, 1] or [−1, 1] or other appropriate ranges).

The thin-mask approximation, also called the Kirchhoff boundary condition, is widely used to simplify the determination of the interaction of the radiation and the patterning device. The thin-mask approximation assumes that the thickness of the structures on the patterning device is very small compared with the wavelength and that the widths of the structures on the mask are very large compared with the wavelength. Therefore, the thin-mask approximation assumes the electromagnetic field after the patterning device is the multiplication of the incident electromagnetic field with the mask transmission function. However, as lithographic processes use radiation of shorter and shorter wavelengths, and the structures on the patterning device become smaller and smaller, the assumption of the thin-mask approximation can break down. For example, interaction of the radiation with the structures (e.g., edges between the top surface and a sidewall) because of their finite thicknesses (“mask 3D effect” or “M3D”) may become significant. Encompassing this scattering in the mask transmission function may enable the mask transmission function to better capture the interaction of the radiation with the patterning device. A mask transmission function under the thin-mask approximation may be referred to as a thin-mask transmission function. A mask transmission function encompassing M3D may be referred to as a M3D mask transmission function.

According to an embodiment of the present disclosure, one or more images may be generated. The images include various types of signals that may be characterized by pixel values or intensity values of each pixel. Depending on the relative values of the pixel within the image, the signal may be referred as, for example, a weak signal or a strong signal, as may be understood by a person of ordinary skill in the art. The term “strong” and “weak” are relative terms based on intensity values of pixels within an image and specific values of intensity may not limit scope of the present disclosure. In an embodiment, the strong and weak signal may be identified based on a selected threshold value. In an embodiment, the threshold value may be fixed (e.g., a midpoint of a highest intensity and a lowest intensity of pixel within the image. In an embodiment, a strong signal may refer to a signal with values greater than or equal to an average signal value across the image and a weak signal may refer to signal with values less than the average signal value. In an embodiment, the relative intensity value may be based on percentage. For example, the weak signal may be signal having intensity less than 50% of the highest intensity of the pixel (e.g., pixels corresponding to target pattern may be considered pixels with highest intensity) within the image. Furthermore, each pixel within an image may considered as a variable. According to the present embodiment, derivatives or partial derivative may be determined with respect to each pixel within the image and the values of each pixel may be determined or modified according to a cost function based evaluation and/or gradient based computation of the cost function. For example, a CTM image may include pixels, where each pixel is a variable that can take any real value.

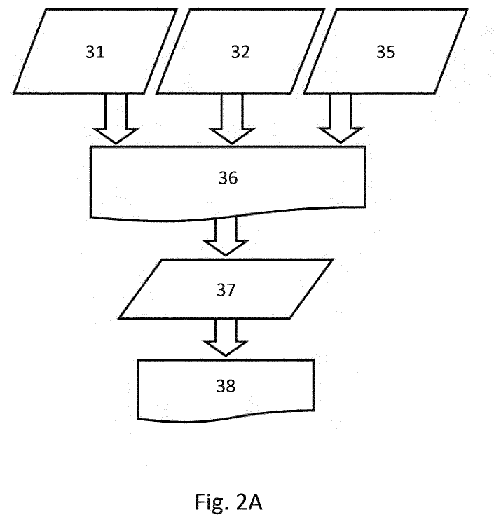

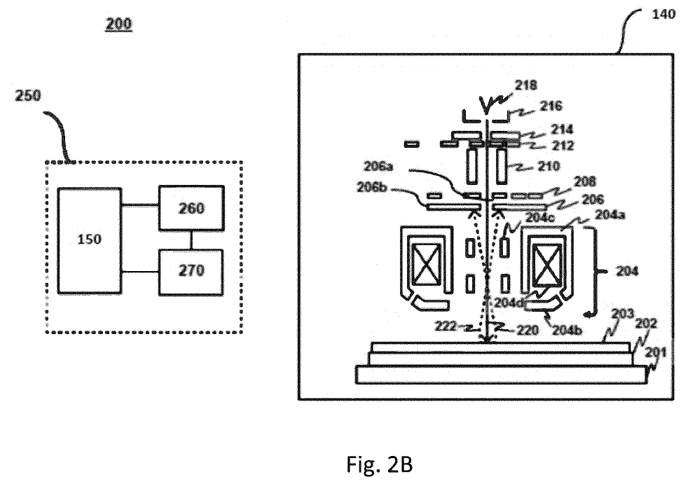

FIG. 2A illustrates an exemplary flow chart for simulating lithography in a lithographic projection apparatus, according to an embodiment of the present disclosure. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, it is noted that source model 31 can represent the optical characteristics of the source that include, but not limited to, numerical aperture settings, illumination sigma (σ) settings as well as any particular illumination shape (e.g., off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as

$$C F ( {z}_{1} , {z}_{2} , ⋯ , {z}_{N} ) = {\sum }_{p = 1}^{P} {w}_{p} {f}_{p}^{2} ( {z}_{1} , {z}_{2} , ⋯ , {z}_{N} ) \qquad ( Eq . 1 )$$

where (z₁, z₂, . . . , z_{N}) are N design variables or values thereof. fₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ(z₁, z₂, . . . , z_{N}). For example, the characteristic may be a position of an edge of a pattern, measured at a given point on the edge. Different fₚ(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value. fₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in Eq. 1. CF(z₁, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, an interlayer characteristic, or a combination thereof. In one embodiment, the design variables (z₁, z₂, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, fₚ(z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

FIG. 2B illustrates schematic diagram of an exemplary imaging system 200 according to embodiments of the present disclosure. Electron beam tool 140 of FIG. 2 may be configured for use in EBI system. Electron beam tool 140 may be a single beam apparatus or a multi-beam apparatus. As shown in FIG. 2, electron beam tool 140 includes a motorized sample stage 201, and a wafer holder 202 supported by motorized sample stage 201 to hold a wafer 203 to be inspected. Electron beam tool 140 further includes an objective lens assembly 204, an electron detector 206 (which includes electron sensor surfaces 206a and 206b), an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Electron beam tool 140 may additionally include an Energy Dispersive X-ray Spectrometer (EDS) detector (not shown) to characterize the materials on wafer 203.

A primary electron beam 220 is emitted from cathode 218 by applying a voltage between anode 216 and cathode 218. Primary electron beam 220 passes through gun aperture 214 and beam limit aperture 212, both of which may determine the size of electron beam entering condenser lens 210, which resides below beam limit aperture 212. Condenser lens 210 focuses primary electron beam 220 before the beam enters objective aperture 208 to set the size of the electron beam before entering objective lens assembly 204. Deflector 204c deflects primary electron beam 220 to facilitate beam scanning on the wafer. For example, in a scanning process, deflector 204c may be controlled to deflect primary electron beam 220 sequentially onto different locations of top surface of wafer 203 at different time points, to provide data for image reconstruction for different parts of wafer 203. Moreover, deflector 204c may also be controlled to deflect primary electron beam 220 onto different sides of wafer 203 at a particular location, at different time points, to provide data for stereo image reconstruction of the wafer structure at that location. Further, in some embodiments, anode 216 and cathode 218 may be configured to generate multiple primary electron beams 220, and electron beam tool 140 may include a plurality of deflectors 204c to project the multiple primary electron beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary electron beam 220 may be immersed in the magnetic field and may be electrically charged, which, in turn, creates an electric field. The electric field reduces the energy of impinging primary electron beam 220 near the surface of wafer 203 before it collides with wafer 203. Control electrode 204b, being electrically isolated from pole piece 204a, controls an electric field on wafer 203 to prevent micro-arching of wafer 203 and to ensure proper beam focus.

A secondary electron beam 222 may be emitted from the part of wafer 203 upon receiving primary electron beam 220. Secondary electron beam 222 may form a beam spot on sensor surfaces 206a and 206b of electron detector 206. Electron detector 206 may generate a signal (e.g., a voltage, a current, etc.) that represents an intensity of the beam spot, and provide the signal to an image processing system 250. The intensity of secondary electron beam 222, and the resultant beam spot, may vary according to the external or internal structure of wafer 203. Moreover, as discussed above, primary electron beam 220 may be projected onto different locations of the top surface of the wafer or different sides of the wafer at a particular location, to generate secondary electron beams 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on sample stage 201, and comprises an electron beam tool 140, as discussed above. Imaging system 200 may also comprise an image processing system 250 that includes an image acquirer 260, storage 270, and controller 150. Image acquirer 260 may comprise one or more processors. For example, image acquirer 260 may comprise a computer, server, mainframe host, terminals, personal computer, any kind of mobile computing devices, and the like, or a combination thereof. Image acquirer 260 may connect with a detector 206 of electron beam tool 140 through a medium such as an electrical conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may be configured to perform adjustments of brightness and contrast, etc. of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, and post-processed images. Image acquirer 260 and storage 270 may be connected to controller 150. In some embodiments, image acquirer 260, storage 270, and controller 150 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image comprising a plurality of imaging areas. The single image may be stored in storage 270. The single image may be an original image that may be divided into a plurality of regions. Each of the regions may comprise one imaging area containing a feature of wafer 203.

As used herein, the term “patterning process” means a process that creates an etched substrate by the application of specified patterns of light as part of a lithography process.

As used herein, the term “target pattern” means an idealized pattern that is to be etched on a substrate.

As used herein, the term “printed pattern” means the physical pattern on a substrate that was formed based on a design layout. The printed pattern can include, for example, vias, contact holes, troughs, channels, depressions, edges, or other two and three dimensional features resulting from a lithography process.

As used herein, the term “process model” means a model that includes one or more models that simulate a patterning process. For example, a process model can include any combination of: an optical model (e.g., that models a lens system/projection system used to deliver light in a lithography process and may include modelling the final optical image of light that goes onto a photoresist), a mask model, a resist model (e.g., that models physical effects of the resist, such as chemical effects due to the light), an OPC model (e.g., that can be used to make design layouts and may include sub-resolution resist features (SRAFs), etc.), an imaging device model (e.g., that models what an imaging device may image from a printed pattern).

As used herein, the term “imaging device” means any number or combination of devices and associated computer hardware and software that can be configured to generate images of a target, such as the printed pattern or portions thereof. Non-limiting examples of an imaging devices can include: scanning electron microscopes (SEMs), x-ray machines, etc.

As used herein, the term “calibrating” means to modify (e.g., improve or tune) and/or validate, such as the process model.

The selection of patterns or gauges utilized with model building or for characterizing stochastic manufacturing processes can be dependent on the degree of variation in such pattern features. When performing 3D resist modeling, the simulated shapes and depth profiles of resist features can be determined as part of simulating the lithographic printing process. However, optimization of some aspects of the process e.g., OPC, can cause changes in other parts of the process, for example, the resist features as determined from a 3D resist model. For example, a resist feature may initially have nearly vertical sides as expected in an ideal case, but during optimization the sides may develop an angle such that the size or shape of the resist feature changes versus depth. In some locations in the pattern such depth variation (and the resultant changes in a CD) may be permissible. Where patterns include features that are more sensitive, such patterns may result in simulated CDs that vary too much and impermissibly reduce the robustness of simulations that predict the simulated CDs. Such variations can interfere with generating robust OPC models used for pattern optimization.

The present disclosure addresses, among other things, characterizing the depth variation of features (for example in a simulated resist layer) and selecting simulated patterns with features that are not impermissibly sensitive based on simulation depth. If performed prior to mask tapeout, further OPC can be performed to reduce pattern sensitivity, thereby making pattern more useful for OPC model building. If after tapeout, OPC model building can be performed specifically with SEM images of features having sufficiently low sensitivity. Similarly, features that have too much sensitivity can be selected for SEM imaging as part of a stochastic modelling process, where such variation can be useful.

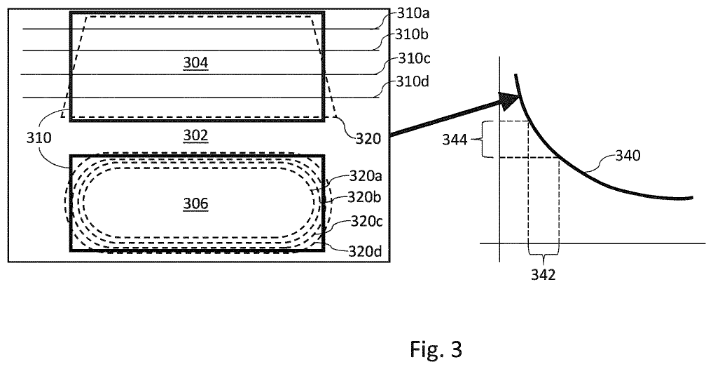

FIG. 3 illustrates exemplary predicted results for a portion of a pattern having a depth variation, according to an embodiment of the present disclosure. FIG. 3 depicts an example ideal resist pattern 310 (e.g., a portion of a resist layer to be utilized for printing a bar, line, etc.). Inset 302 shows the target 310 in a side view 304 and atop view 306. Feature 320 is the simulated pattern but, as seen in side view 304, may have a depth variation. Four depths 310a-d are shown at which a lithography simulation (e.g., a resist model) can generate predicted shapes 320a-d (e.g., a resist contours) of the feature 320 on a resist layer. Such depths can vary between the top surface (e.g., 0 nm.) to the bottom surface (e.g., 37 nm) and can include any number of intermediate depths (e.g., 3, 5, 7, nm. steps), and any combination thereof of such possible depths. Examples of the corresponding predicted shapes 320a-d of feature 320 are shown in top view 306 along with a top view of target feature 310 for comparison.

In some embodiments, metrics such as a CD in a particular direction at a given gauge can be determined to quantify the variation of the predicted shape. As shown by the example curve 340, for a change 342 in depth, there can be a corresponding change 344 in CD. In this example, the size (length and width, and corresponding CD) is simulated to be smaller at depth 310a than 310d. This is also seen by shapes 320a-d increasing in size with corresponding depths 310a-d. However, the change in CD versus depth may be complex and need not be linear. This is reflected in curve 340 showing that as the depth increases, the corresponding change in CD decreases. Stated another way, a simulated feature may have a sensitivity (simulated variation) that varies with depth. In particular, different features/patterns can have different sensitivities and can thereby be useful or not useful for applications related to OPC model building or stochastic modelling. Accordingly, in some embodiments, patterns gauges, etc. can be selected based on simulated images (e.g., an aerial image) at depths where the sensitivity of the predicted result is generally lower than it is at some other depths. By quantifying the AI depth sensitivity of a feature, various features/patterns can be selected that produce more robust models (e.g., OPC models). As used herein, the term “AI depth sensitivity” means the variation in a metric of the feature as a function of depth within the simulated pattern (e.g., based on an aerial image). While many examples herein utilize AI depth variation and variation sensitivity as indicators, the present disclosure contemplates that any method of quantifying the variation of a feature as a function of depth can be utilized for a substantively similar analysis and with any of the disclosed embodiments, such as etch depth variation, resist depth variation, etc.

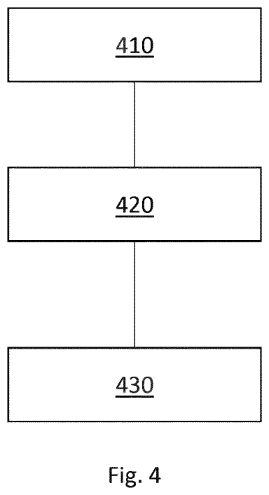

FIG. 4 illustrates an exemplary process for selecting patterns or gauges based on a depth variation evaluation, according to an embodiment of the present disclosure. At 410, a method can include characterizing a depth variation of a predicted result (e.g., predicted shape(s) 320a-d) within a feature (e.g., feature 320) of a pattern from a lithography simulation. In some embodiments, the predicted result can represent a resist contour or a resist CD. Accordingly, the depth variation characterization can be a resist contour variation in depth or a resist CD variation in depth. In other embodiments, the predicted result can represent an aerial image contour or an aerial image CD. Accordingly, the depth variation characterization can be an aerial image contour variation in depth or an aerial image CD variation in depth. In some other embodiments, the predicted result can represent an etch contour or an etch CD. Accordingly, the depth variation characterization can be an etch contour variation in depth or an etch CD variation in depth.

At 420, the method can include evaluating the depth variation characterization. In some embodiments, the evaluating can be based on an aerial image depth sensitivity having the depth variation.

At 430, the method can include selecting patterns or gauges based on the depth variation evaluation. As previously mentioned, the selection can be based on the stage in a lithographic manufacturing process and can also be based on a desired application of the selected patterns and gauges (e.g., for performing OPC or stochastic modelling, as described further herein).

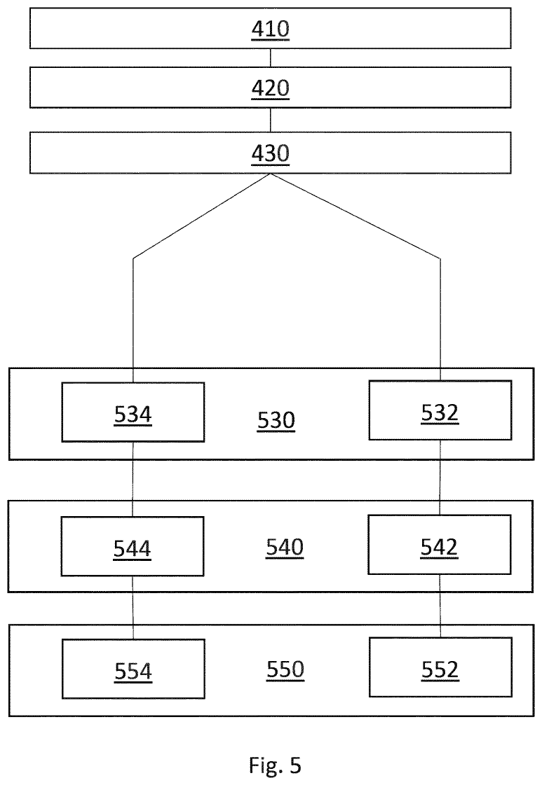

FIG. 5 illustrates an exemplary process for various operations that can be performed based on a process stage and an evaluation of the AI depth sensitivity, according to an embodiment of the present disclosure. The general process described in FIG. 4 is reproduced in FIG. 5, but with the addition of optional processes, which can be present in any combination according to various embodiments. The right branch depicts processes (e.g., processes 532, 542, and 552) where the selecting is based on the aerial image depth sensitivity being less than a threshold. The left branch depicts processes (e.g., processes 534, 544, 554), where the selecting is based on the aerial image depth sensitivity being greater than a threshold. In some embodiments, the AI depth sensitivity can be based on a first derivative of a CD as a function of depth (e.g., the derivative of curve 340), e.g., with the threshold being a derivative of a certain value at a local location along curve 340. In other embodiments, the AI depth sensitivity can be based on a total change in CD compared to a total change in depth. For example, were curve 340 to have a local flattening a range of depths could be considered as sensitive if such a range included a portion with a steep change in CD. Conversely, if there was a only small transient change in sensitivity, such a range might not be considered sensitive.

These processes are further illustrated as being performed at different stages (530, 540, 550) in the lithographic process. While the processes described below are with reference to a particular stage that provides various technical benefits, such are provided as examples only and the processes can be performed at any suitable stage of the lithography process.

In some embodiments, when AI location sensitivities are less than a threshold, the embodiments can include performing OPC modelling utilizing the patterns or gauges. Because the selected patterns or gauges may be relatively insensitive to depth, such features can be robust and provide a consistent and accurate basis for an OPC model. In this way, an OPC model can provide corrections that can produce expected results throughout the depth of the feature being corrected. In contrast, when a pattern or gauge has an AI sensitivity greater than a threshold, the present disclosure provides other processes based on the lithography stage for reducing the AI depth sensitivity, selecting patterns or gauges, etc. Such reductions in AI depth sensitivity can make such features suitable for OPC modelling.

It can be advantageous to have a mask design be optimized as much as possible before utilizing a mask in the actual lithographic process. As such, (referring back to FIG. 5) at pre-tapeout stage 530, which can be before a mask design is finalized, process 532 can be performed and include selecting gauges or patterns with AI depth sensitivity less than a threshold for SEM imaging.

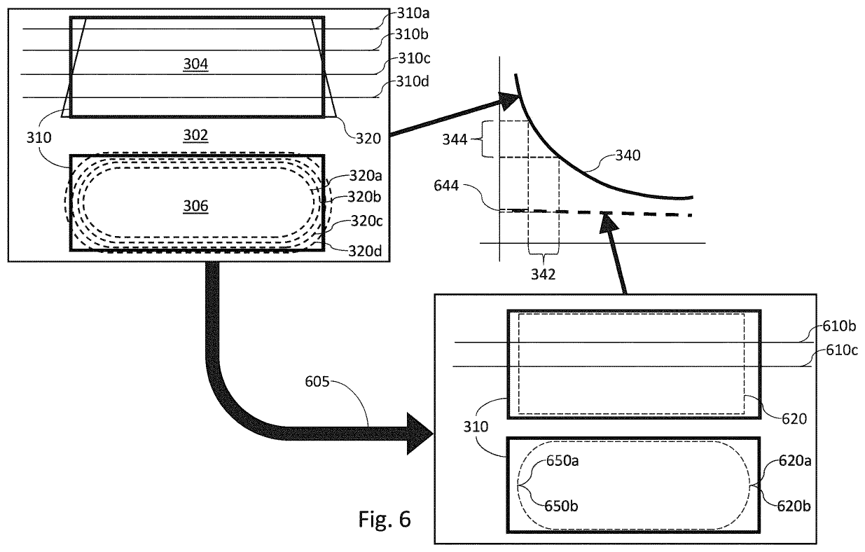

FIG. 6 illustrates an exemplary process for reducing a depth variation of a pattern, according to an embodiment of the present disclosure. Referring back to FIG. 5, in some embodiments, pre-tapeout stage 530 can include performing process 534 for reducing the depth variation. As detailed in FIG. 6, process 534 can include performing local OPC on the feature in the pattern, at one or more locations where the AI depth sensitivity is greater than the threshold, to reduce a depth variation of the pattern. Such local OPC can include detecting a hotspot location in the pattern and performing the local OPC at the hotspot location. Examples of hotspots can include pinching, bridging, etc.

FIG. 6 reproduces feature 320 and the predicted shapes 320a-d, where in this example, the sensitivity depicted by curve 340 is above a threshold. Performing local OPC 605 can reduce a difference between a first contour 620a of the feature 620 at a first depth 610b and a second contour 620b (depicted here as essentially overlaying first contour 620a) of the feature 620 at a second depth 610c. The present disclosure contemplates that OPC can be utilized to perform pattern improvement in numerous ways. Comparing the change 344 in CD before OPC and the change 644 in CD after OPC it can be seen that feature 620 is less sensitive. The example provided in FIG. 6 also illustrates that the reduced sensitivity can be reflected in a change in a side wall angle of the feature. Because the contours can define a calculated side wall angle, the (reduced) difference can be between a first location 650a on the first contour 620a and a second location 650b on the second contour 620b, the difference determining a side wall angle of feature 620. Again, the depicted example illustrates a highly corrected feature with a side wall angle of approximately 90 degrees, but other extents of correction are possible based on the OPC optimization.

Returning to FIG. 5, post-tapeout stage 540 can include a process 544 that can be post-tapeout but before at least some SEM image acquisition. In some embodiments, process 544 can include generating SEM images of the pattern while excluding a portion of the SEM images where the AI depth sensitivity is above the threshold. The method can also include performing OPC model building utilizing the SEM images. Configuring the lithography process to exclude patterns or gauges of higher sensitivity can improve the lithography process by not requiring SEM image acquisition time and processing of SEM images that may lead to instability in OPC models. In other embodiments, process 544 can also include generating SEM images of the pattern where the AI depth sensitivity is above the threshold. Here, the method can also include performing stochastic modelling utilizing the SEM images.

Post SEM stage 550 include embodiments that include obtaining SEM images of the selected patterns or gauges. Here, with the SEM images already obtained, various embodiments are disclosed that allow for data cleaning, efficient stochastic modeling, etc. Some embodiments can include, at process 552, utilizing already obtained SEM images for OPC modelling that have features with AI location sensitivities below the threshold.

In acquiring SEM images of a wafer, it is possible that such SEM images can include both those having features with AI depth sensitivity below the threshold and above the threshold. In some embodiments of process 554, the obtaining can include discarding a portion of the SEM images where the aerial image depth sensitivity is above the threshold. Because the remaining SEM images (of lower-sensitivity patterns or gauges) may be advantageous for performing OPC modeling, some embodiments can include performing OPC model building utilizing the SEM images without the discarded portion.

Also, other embodiments of process 554 can include performing stochastic modelling of the pattern based on a portion of the SEM images where the aerial image depth sensitivity is above the threshold. In some embodiments this can include calibrating a stochastic failure model based on the portion of the SEM images in a manner similar to that described previously with regard to process 544.

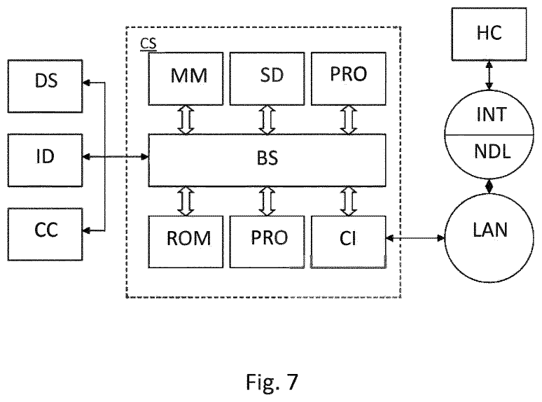

FIG. 7 is a block diagram of an example computer system CS, according to an embodiment of the present disclosure.

Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

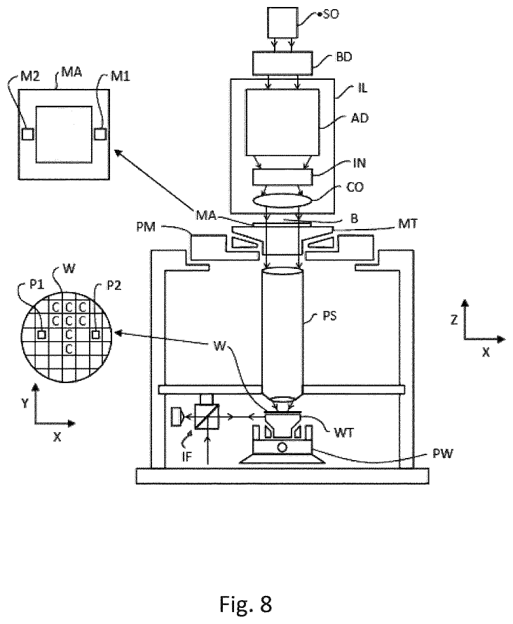

FIG. 8 is a schematic diagram of a lithographic projection apparatus, according to an embodiment of the present disclosure.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning apparatuses, such as a beam expander Ex, for example. The illuminator IL may comprise adjusting device AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning apparatus (and interferometric measuring apparatus IF), the substrate table WT can be moved accurately, e.g., so as to position different target portions C in the path of beam PB. Similarly, the first positioning apparatus can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

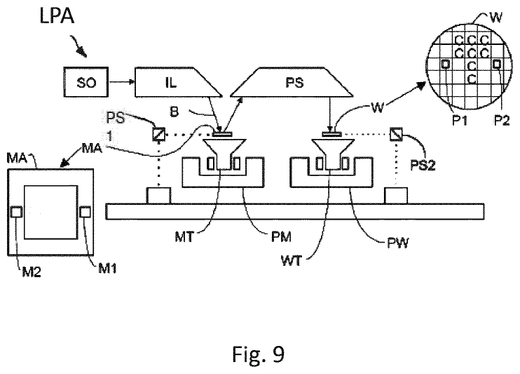

FIG. 9 is a schematic diagram of another lithographic projection apparatus (LPA), according to an embodiment of the present disclosure.

LPA can include source collector module SO, illumination system (illuminator) IL configured to condition a radiation beam B (e.g., EUV radiation), support structure MT, substrate table WT, and projection system PS.

Support structure (e.g., a patterning device table) MT can be constructed to support a patterning device (e.g., a mask or a reticle) MA and connected to a first positioner PM configured to accurately position the patterning device;

Substrate table (e.g., a wafer table) WT can be constructed to hold a substrate (e.g., a resist coated wafer) W and connected to a second positioner PW configured to accurately position the substrate.

Projection system (e.g., a reflective projection system) PS can be configured to project a pattern imparted to the radiation beam B by patterning device MA onto a target portion C (e.g., comprising one or more dies) of the substrate W.

As here depicted, LPA can be of a reflective type (e.g., employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultraviolet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as a-outer and a-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g., patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g., patterning device table) MT and the substrate table WT are scanned synchronously while a pattern imparted to the radiation beam is projected onto target portion C (i.e. a single dynamic exposure). The velocity and direction of substrate table WT relative to the support structure (e.g., patterning device table) MT may be determined by the (de-)magnification and image reversal characteristics of the projection system PS.

In stationary mode, the support structure (e.g., patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array.

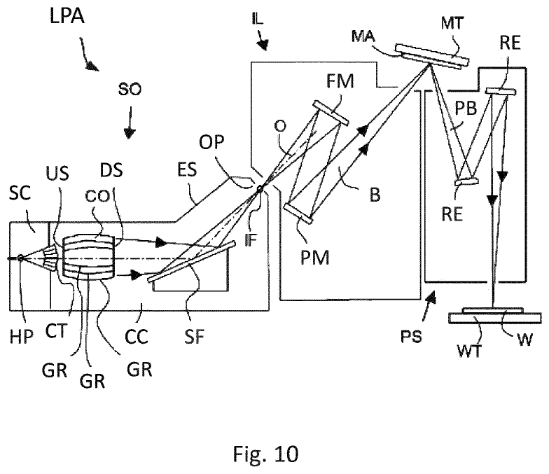

FIG. 10 is a detailed view of the lithographic projection apparatus, according to an embodiment of the present disclosure.

As shown, LPA can include the source collector module SO, the illumination system IL, and the projection system PS. The source collector module SO is constructed and arranged such that a vacuum environment can be maintained in an enclosing structure ES of the source collector module SO. An EUV radiation emitting hot plasma HP may be formed by a discharge produced plasma source. EUV radiation may be produced by a gas or vapor, for example Xe gas, Li vapor or Sn vapor in which the hot plasma HP is created to emit radiation in the EUV range of the electromagnetic spectrum. The hot plasma HP is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma HP is passed from a source chamber SC into a collector chamber CC via an optional gas barrier or contaminant trap CT (in some cases also referred to as contaminant barrier or foil trap) which is positioned in or behind an opening in source chamber SC. The contaminant trap CT may include a channel structure. Contamination trap CT may also include a gas barrier or a combination of a gas barrier and a channel structure. The contaminant trap or contaminant barrier CT further indicated herein at least includes a channel structure, as known in the art.

The collector chamber CC may include a radiation collector CO which may be a so-called grazing incidence collector. Radiation collector CO has an upstream radiation collector side US and a downstream radiation collector side DS. Radiation that traverses radiation collector CO can be reflected off a grating spectral filter SF to be focused in a virtual source point IF along the optical axis indicated by the dot-dashed line ‘O’. The virtual source point IF can be referred to as the intermediate focus, and the source collector module can be arranged such that the intermediate focus IF is located at or near an opening OP in the enclosing structure ES. The virtual source point IF is an image of the radiation emitting plasma HP.

Subsequently the radiation traverses the illumination system IL, which may include a facetted field mirror device FM and a facetted pupil mirror device PM arranged to provide a desired angular distribution of the radiation beam B, at the patterning device MA, as well as a desired uniformity of radiation amplitude at the patterning device MA. Upon reflection of the beam of radiation B at the patterning device MA, held by the support structure MT, a patterned beam PB is formed and the patterned beam PB is imaged by the projection system PS via reflective elements RE onto a substrate W held by the substrate table WT.

More elements than shown may generally be present in illumination optics unit IL and projection system PS. The grating spectral filter SF may optionally be present, depending upon the type of lithographic apparatus. Further, there may be more mirrors present than those shown in the figures, for example there may be 1-6 additional reflective elements present in the projection system PS.

Collector optic CO can be a nested collector with grazing incidence reflectors GR, just as an example of a collector (or collector mirror). The grazing incidence reflectors GR are disposed axially symmetric around the optical axis O and a collector optic CO of this type may be used in combination with a discharge produced plasma source, often called a DPP source.

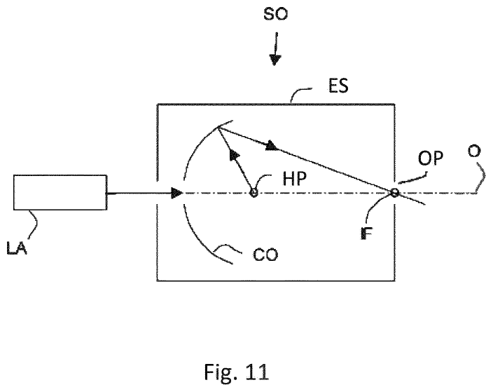

FIG. 11 is a detailed view of source collector module SO of lithographic projection apparatus LPA, according to an embodiment of the present disclosure.

Source collector module SO may be part of an LPA radiation system. A laser LA can be arranged to deposit laser energy into a fuel, such as xenon (Xe), tin (Sn) or lithium (Li), creating the highly ionized plasma HP with electron temperatures of several 10's of eV. The energetic radiation generated during de-excitation and recombination of these ions is emitted from the plasma, collected by a near normal incidence collector optic CO and focused onto the opening OP in the enclosing structure ES.

The concepts disclosed herein may simulate or mathematically model any generic imaging system for imaging sub wavelength features and may be especially useful with emerging imaging technologies capable of producing increasingly shorter wavelengths. Emerging technologies already in use include EUV (extreme ultraviolet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

Embodiments of the present disclosure can be further described by the following clauses.

1. A method comprising:
characterizing a depth variation of a predicted result within a feature of a pattern from a lithography simulation;
evaluating the depth variation characterization; and
selecting patterns or gauges based on the depth variation evaluation.
   2. The method of clause 1, wherein the predicted result represents a resist contour or a resist CD; and the depth variation characterization is a resist contour variation in depth or a resist CD variation in depth.
   3. The method of clause 1, wherein the predicted result represents an aerial image contour or an aerial image CD; and the depth variation characterization is aerial image contour variation in depth or an aerial image CD variation in depth.
   4. The method of clause 1, wherein the predicted result represents an etch contour or an etch CD; and the depth variation characterization is etch contour variation in depth or an etch CD variation in depth.
   5. The method of clause 1, wherein the evaluating is based on an aerial image (AI) depth sensitivity having the depth variation.
   6. The method of clause 5, wherein the AI depth sensitivity is based on a first derivative of a CD as a function of depth.
   7. The method of clause 5, wherein the AI depth sensitivity is based on a total change in CD compared to a total change in depth.
   8. The method of clause 5, wherein the selecting is based on the aerial image depth sensitivity being less than a threshold.
   9. The method of clause 8, further comprising performing optical proximity correction (OPC) modelling utilizing the patterns or gauges.
   10. The method of clause 5, wherein the selecting is based on the aerial image depth sensitivity being greater than a threshold.
   11. The method of clause 10, further comprising performing local OPC on the feature in the pattern where the aerial image depth sensitivity is greater than the threshold to reduce a depth variation of the pattern, the local OPC comprising:
detecting a hotspot location in the pattern; and
performing the local OPC at the hotspot location.
   12. The method of clause 11, wherein the local OPC reduces a difference between a first contour of the feature at a first depth and a second contour of the feature at a second depth.
   13. The method of clause 12, wherein the difference is between a first location on the first contour and a second location on the second contour, the difference determining a side wall angle of the feature.
   14. The method of clause 10, further comprising:
generating SEM images of the pattern while excluding a portion of the SEM images where the aerial image depth sensitivity is above the threshold; and
performing OPC model building utilizing the SEM images.
   15. The method of clause 10, further comprising:
generating SEM images of the pattern where the aerial image depth sensitivity is above the threshold; and
performing stochastic modelling utilizing the SEM images.
   16. The method of clause 10, further comprising obtaining SEM images of the selected patterns or gauges
   17. The method of clause 16, the obtaining comprising discarding a portion of the SEM images where the aerial image depth sensitivity is above the threshold.
   18. The method of clause 17, further comprising performing OPC model building utilizing the SEM images.
   19. The method of clause 16, further comprising performing stochastic modelling of the pattern based on a portion of the SEM images where the aerial image depth sensitivity is above the threshold.
   20. The method of clause 16, the evaluating further comprising calibrating a stochastic failure model based on a portion of the SEM images.
   21. A non-transitory computer readable medium having instructions recorded thereon, the instructions when executed by a computer having at least one programmable processor cause operations as in any of clauses 1-20.
   22. A system comprising:
at least one programmable processor; and
a non-transitory computer readable medium having instructions recorded thereon, the instructions when executed by a computer having the at least one programmable processor cause operations as in any of clauses 1-20.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The combinations and sub-combinations of the elements disclosed herein constitute separate embodiments and are provided as examples only. Also, the descriptions above are intended to be illustrative, not limiting. Thus, it will be apparent to one skilled in the art that modifications may be made as described without departing from the scope of the claims set out below.

1. A non-transitory computer readable medium having instructions recorded thereon or therein, the instructions, when executed by at least one programmable processor, are configured to cause the at least one programmable processor to at least:
characterize a depth variation of a predicted result within a feature of a pattern from a lithography simulation;
evaluate the depth variation characterization; and
select patterns or gauges based on the depth variation evaluation.

2. The medium of claim 1, wherein the predicted result represents a resist contour or a resist CD; and the depth variation characterization is a resist contour variation in depth or a resist CD variation in depth.

3. The medium of claim 1, wherein the predicted result represents an aerial image contour or an aerial image CD; and the depth variation characterization is aerial image contour variation in depth or an aerial image CD variation in depth.

4. The medium of claim 1, wherein the predicted result represents an etch contour or an etch CD; and the depth variation characterization is etch contour variation in depth or an etch CD variation in depth.

5. The medium of claim 1, wherein the instructions configured to cause the at least one programmable processor to evaluate the depth variation characterization are configured to cause the at least one programmable processor to evaluate the depth variation characterization based on an aerial image (AI) depth sensitivity having the depth variation.

6. The medium of claim 5, wherein the AI depth sensitivity is based on a first derivative of a CD as a function of depth.

7. The medium of claim 5, wherein the AI depth sensitivity is based on a total change in CD compared to a total change in depth.

8. The medium of claim 5, wherein the instructions configured to cause the at least one programmable processor to select patterns or gauges based on the depth variation evaluation are further configured to cause the at least one programmable processor to select patterns or gauges based on the aerial image depth sensitivity being less than a threshold.

9. The medium of claim 8, wherein the instructions are further configured to cause the at least one programmable processor to perform optical proximity correction (OPC) modelling utilizing the patterns or gauges.

10. The medium of claim 5, wherein the instructions are further configured to cause the at least one programmable processor to perform further local OPC on the feature in the pattern where the aerial image depth sensitivity is greater than the threshold to reduce a depth variation of the pattern, the local OPC comprising:
detection of hotspot location in the pattern; and
performance of the local OPC at the hotspot location.

11. The medium of claim 10, wherein the local OPC reduces a difference between a first contour of the feature at a first depth and a second contour of the feature at a second depth.

12. The medium of claim 5, wherein the instructions are further configured to cause the at least one programmable processor to:
generate SEM images of the pattern while excluding a portion of the SEM images where the aerial image depth sensitivity is above the threshold; and
perform OPC model building utilizing the SEM images.

13. The medium of claim 5, wherein the instructions are further configured to cause the at least one programmable processor to:
generate SEM images of the pattern where the aerial image depth sensitivity is above the threshold; and
perform stochastic modelling utilizing the SEM images.

14. The medium of claim 5, wherein the instructions are further configured to cause the at least one programmable processor to:
obtain SEM images of the selected patterns or gauges; and
discard a portion of the SEM images where the aerial image depth sensitivity is above the threshold.

15. The medium of claim 5, wherein the instructions are further configured to cause the at least one programmable processor to:
obtain SEM images of the selected patterns or gauges;
perform stochastic modelling of the pattern based on a portion of SEM images where the aerial image depth sensitivity is above the threshold; or
calibrate a stochastic failure model based on a portion of SEM images.

16. A method comprising:
characterizing a depth variation of a predicted result within a feature of a pattern from a lithography simulation;
evaluating the depth variation characterization; and
selecting, by a hardware computer system, patterns or gauges based on the depth variation evaluation.

17. The method of claim 16, wherein the predicted result represents a resist contour or a resist CD; and the depth variation characterization is a resist contour variation in depth or a resist CD variation in depth.

18. The method of claim 16, wherein the predicted result represents an aerial image contour or an aerial image CD; and the depth variation characterization is aerial image contour variation in depth or an aerial image CD variation in depth.

19. The method of claim 16, wherein the predicted result represents an etch contour or an etch CD; and the depth variation characterization is etch contour variation in depth or an etch CD variation in depth.

20. The method of claim 16, wherein the evaluating is based on an aerial image (AI) depth sensitivity having the depth variation.
